(19) United States
(12) Patent Application Publication
(10) Pub. No.: US 2024/0146011 A1
(43) Pub. Date: May 2, 2024

(54) GAS LASER DEVICE AND ELECTRONIC DEVICE MANUFACTURING METHOD

(71) Applicant: Gigaphoton Inc., Tochigi (JP)

(72) Inventors: Koji ASHIKAWA, Oyama-shi (JP); Shinichi MATSUMOTO, Oyama-shi (JP)

(73) Assignee: Gigaphoton Inc., Tochigi (JP)

(21) Appl. No.: 18/408,777

(22) Filed: Jan. 10, 2024

Related U.S. Application Data
(63) Continuation of application No. PCT/JP2021/029195, filed on Aug. 5, 2021.

(51) Int. Cl. H01S 3/034; H01S 3/036; H01S 3/038; H01S 3/134; H01S 3/225

(52) U.S. Cl. CPC H01S 3/034; H01S 3/036; H01S 3/038; H01S 3/134; H01S 3/225

(57) ABSTRACT

A gas laser device includes a chamber device including electrodes at an inside thereof to be filled with laser gas and configured to output, through a window to an outside thereof, light generated from the laser gas when a voltage is applied to the electrodes; a mirror arranged at the outside of the chamber device and configured to reflect at least a part of the light output through the window; a holding portion holding the mirror; a support member configured to support the holding portion to be movable along a plane perpendicular to an optical axis of the light output through the window; a moving mechanism configured to move the holding portion with respect to the support member along the plane; and an angle maintaining mechanism configured to maintain an inclination angle of the holding portion with respect to the support member at a predetermined angle.

### CROSS-REFERENCE TO RELATED APPLICATIONS

The present application claims the benefit of International Application No. PCT/JP2021/029195, filed on Aug. 5, 2021, the entire contents of which are hereby incorporated by reference.

### BACKGROUND

### 1. Technical Field

The present disclosure relates to a gas laser device and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248.0 nm and an ArF excimer laser device for outputting laser light having a wavelength of about 193.4 nm are used.

The KrF excimer laser device and the ArF excimer laser device each have a large spectral line width of about 350 pm to 400 pm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be narrowed to the extent that the chromatic aberration can be ignored. For this purpose, there is a case in which a line narrowing module (LNM) including a line narrowing element (etalon, grating, and the like) is provided in a laser resonator of the gas laser device to narrow a spectral line width. In the following, a gas laser device with a narrowed spectral line width is referred to as a line narrowing gas laser device.

### LIST OF DOCUMENTS

### Patent Documents

Patent Document 1: Japanese Patent Application Publication No. H11-330592
Patent Document 2: Japanese Unexamined Utility Model Application Publication No. H3-73474
Patent Document 3: Japanese Patent Application Publication No. H10-144987

### SUMMARY

A gas laser device according to an aspect of the present disclosure includes a chamber device including electrodes at an inside thereof to be filled with laser gas and configured to output, through a window to an outside thereof, light generated from the laser gas when a voltage is applied to the electrodes; a mirror arranged at the outside of the chamber device and configured to reflect at least a part of the light output through the window; a holding portion holding the mirror; a support member configured to support the holding portion to be movable along a plane perpendicular to an optical axis of the light output through the window; a moving mechanism configured to move the holding portion with respect to the support member along the plane; and an angle maintaining mechanism configured to maintain an inclination angle of the holding portion with respect to the support member at a predetermined angle.

An electronic device manufacturing method according to an aspect of the present disclosure includes generating laser light using a gas laser device, outputting the laser light to an exposure apparatus, and exposing a photosensitive substrate to the laser light in the exposure apparatus to manufacture an electronic device. Here, the gas laser device includes a chamber device including electrodes at an inside thereof to be filled with laser gas and configured to output, through a window to an outside thereof, light generated from the laser gas when a voltage is applied to the electrodes; a mirror arranged at the outside of the chamber device and configured to reflect at least a part of the light output through the window; a holding portion holding the mirror; a support member configured to support the holding portion to be movable along a plane perpendicular to an optical axis of the light output through the window; a moving mechanism configured to move the holding portion with respect to the support member along the plane; and an angle maintaining mechanism configured to maintain an inclination angle of the holding portion with respect to the support member at a predetermined angle.

### BRIEF DESCRIPTION OF THE DRAWINGS

Embodiments of the present disclosure will be described below merely as examples with reference to the accompanying drawings.

FIG. 1 is a schematic view showing a schematic configuration example of an entire electronic device manufacturing apparatus.

FIG. 2 is a schematic view showing a schematic configuration example of an entire gas laser device of a comparative example.

FIG. 3 is a front view of an output-side holding unit of the comparative example.

FIG. 4 is a side view of the output-side holding unit shown in FIG. 3.

FIG. 5 is a front view of an output coupling mirror.

FIG. 6 is a front view of the output-side holding unit of a first embodiment.

FIG. 7 is a side view of the output-side holding unit shown in FIG. 6.

FIG. 8 is a side view of the output-side holding unit of a second embodiment.

FIG. 9 is a view showing the relative positional relationship between the output coupling mirror and a radiation spot in the second embodiment.

FIG. 10 is a diagram showing an example of a control flowchart in the second embodiment.

FIG. 11 is a view showing the relative positional relationship between the output coupling mirror and the radiation spot in a third embodiment.

FIG. 12 is a diagram showing a part of an example of a control flowchart in the third embodiment.

FIG. 13 is a diagram showing a remaining part of the example of the control flowchart in the third embodiment.

### DESCRIPTION OF EMBODIMENTS

1. Description of electronic device manufacturing apparatus used in exposure process for electronic device
2. Description of gas laser device of comparative example
   2.1 Configuration
   2.2 Operation
   2.3 Problem
3. Description of gas laser device of first embodiment
   3.1 Configuration
   3.2 Operation
   3.3 Effect
4. Description of gas laser device of second embodiment
   4.1 Configuration
   4.2 Operation
   4.3 Effect
5. Description of gas laser device of third embodiment
   5.1 Configuration
   5.2 Operation
   5.3 Effect

Hereinafter, embodiments of the present disclosure will be described in detail with reference to the drawings.

The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Description of Electronic Device Manufacturing Apparatus Used in Exposure Process for Electronic Device

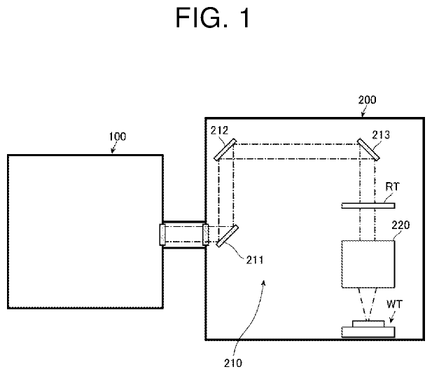

FIG. 1 is a schematic view showing a schematic configuration example of an entire electronic device manufacturing apparatus used in an exposure process for an electronic device. As shown in FIG. 1, the manufacturing apparatus used in the exposure process includes a gas laser device 100 and an exposure apparatus 200. The exposure apparatus 200 includes an illumination optical system 210 including a plurality of mirrors 211, 212, 213 and a projection optical system 220. The illumination optical system 210 illuminates a reticle pattern of a reticle stage RT with laser light incident from the gas laser device 100. The projection optical system 220 causes the laser light transmitted through the reticle to be imaged as being reduced and projected on a workpiece (not shown) arranged on a workpiece table WT. The workpiece is a photosensitive substrate such as a semiconductor wafer on which photoresist is applied. The exposure apparatus 200 synchronously translates the reticle stage RT and the workpiece table WT. to expose the workpiece to the laser light reflecting the reticle pattern. Through the exposure process as described above, a device pattern is transferred onto the semiconductor wafer, thereby a semiconductor device, which is the electronic device, can be manufactured.

### 2. Description of Gas Laser Device of Comparative Example

### 2.1 Configuration

The gas laser device of a comparative example will be described. The comparative example of the present disclosure is an example recognized by the applicant as known only by the applicant, and is not a publicly known example admitted by the applicant.

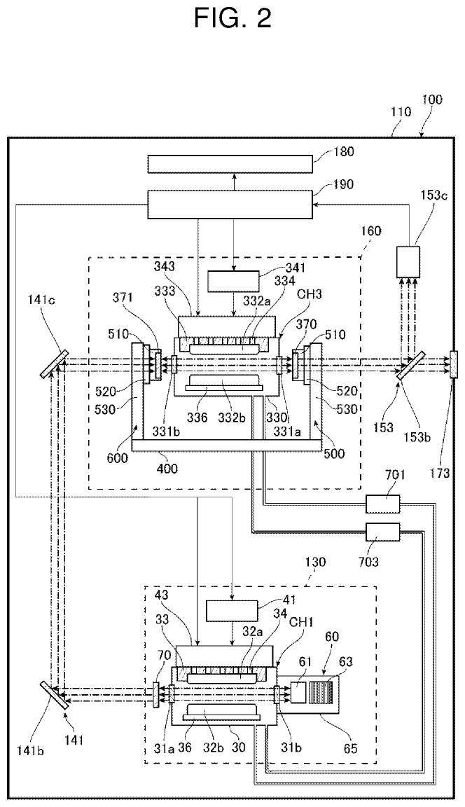

FIG. 2 is a schematic view showing a schematic configuration example of the entire gas laser device 100 of the present example.

The gas laser device 100 is, for example, an ArF excimer laser device using a mixed gas including argon (Ar), fluorine (F2), and neon (Ne). The gas laser device 100 outputs laser light having a center wavelength of about 193.4 nm. Here, the gas laser device 100 may be a gas laser device other than the ArF excimer laser device, and may be, for example, a KrF excimer laser device using a mixed gas including krypton (Kr), F2, and Ne. In this case, the gas laser device 100 outputs laser light having a center wavelength of about 248.0 nm. The mixed gas containing Ar, F2, and Ne which is a laser medium and the mixed gas containing Kr, F2, and Ne which is a laser medium may be referred to as a laser gas. In the mixed gas used in each of the ArF excimer laser device and the KrF excimer laser device, helium (He) may be used instead of Ne.

The gas laser device 100 of the present example includes a housing 110, a laser oscillator 130 that is a master oscillator arranged in an internal space of the housing 110, a light transmission unit 141, an amplifier 160 that is a power oscillator, a detection unit 153, a display unit 180, a processor 190, a laser gas exhaust device 701, and a laser gas supply device 703 as a main configuration.

The laser oscillator 130 includes a chamber device CH1, a charger 41, a pulse power module 43, a line narrowing module 60, and an output coupling mirror 70 as a main configuration.

In FIG. 2, the internal configuration of the chamber device CH1 is shown as viewed from a direction substantially perpendicular to the travel direction of the laser light. The chamber device CH1 includes a housing 30, a pair of windows 31a, 31b, a pair of electrodes 32a, 32b, an insulating portion 33, a feedthrough 34, and an electrode holder portion 36 as a main configuration.

The laser gas is supplied from the laser gas supply device 703 to the internal space of the housing 30 via a pipe, and filled into the internal space in a sealed manner. The internal space is a space in which light is generated by excitation of the laser medium in the laser gas. This light travels to the windows 31a, 31b.

The window 31a is arranged at a wall surface of the housing 30 on the front side in the travel direction of the laser light from the gas laser device 100 to the exposure apparatus 200, and the window 31b is arranged at a wall surface of the housing 30 on the rear side in the travel direction. The windows 31a, 31b are inclined at the Brewster angle with respect to the travel direction of the laser light so that P-polarized light of the laser light is suppressed from being reflected. The output surfaces of the windows 31a, 31b are flat surfaces.

The electrodes 32a, 32b are arranged to face each other at the internal space of the housing 30, and the longitudinal direction of the electrodes 32a, 32b are along the travel direction of the light generated by the high voltage applied between the electrode 32a and the electrode 32b. The space between the electrode 32a and the electrode 32b in the housing 30 is sandwiched between the window 31a and the window 31b. The electrodes 32a, 32b are discharge electrodes for exciting the laser medium by glow discharge. In the present example, the electrode 32a is the cathode and the electrode 32b is the anode.

The electrode 32a is supported by the insulating portion 33. The insulating portion 33 blocks an opening formed in the housing 30. The insulating portion 33 includes an insulator. Further, the feedthrough 34 made of a conductive member is arranged in the insulating portion 33. The feedthrough 34 applies a voltage, to the electrode 32a, supplied from the pulse power module 43. The electrode 32b is supported by the electrode holder portion 36 and is electrically connected to the electrode holder portion 36.

The charger 41 is a DC power source device that charges a capacitor (not shown) provided in the pulse power module 43 with a predetermined voltage. The charger 41 is arranged outside the housing 30 and is connected to the pulse power module 43. The pulse power module 43 includes a switch (not shown) controlled by the processor 190. The pulse power module 43 is a voltage application circuit that, when the switch is turned ON from OFF by the control, boosts the voltage applied from the charger 41 to generate a pulse high voltage, and applies the high voltage to the electrodes 32a, 32b. When the high voltage is applied, discharge occurs between the electrode 32a and the electrode 32b. The energy of the discharge excites the laser medium in the housing 30. When the excited laser gas shifts to a ground level, light is emitted, and the emitted light is transmitted through the windows 31a, 31b and is output to the outside of the housing 30.

The line narrowing module 60 includes a housing 65, a prism 61 arranged at the internal space of the housing 65, a grating 63, and a rotation stage (not shown). An opening is formed in the housing 65, and the housing 65 is connected to the rear side of the housing 30 via the opening.

The prism 61 expands the beam width of the light output from the window 31b and causes the light to be incident on the grating 63. The prism 61 also reduces the beam width of the light reflected from the grating 63 and returns the light to the internal space of the housing 30 through the window 31b. The prism 61 is supported by the rotation stage and is rotated by the rotation stage. The incident angle of the light with respect to the grating 63 is changed by the rotation of the prism 61. Therefore, by rotating the prism 61, the wavelength of the light returning from the grating 63 to the housing 30 via the prism 61 can be selected. Although FIG. 2 shows an example in which one prism 61 is arranged, at least one prism may be arranged.

The surface of the grating 63 is configured of a material having a high reflectance, and a large number of grooves are formed on the surface at predetermined intervals. The grating 63 is a dispersive optical element. The cross sectional shape of each groove is, for example, a right triangle. The light incident on the grating 63 from the prism 61 is reflected by these grooves and diffracted in a direction corresponding to the wavelength of the light. The grating 63 is arranged in the Littrow arrangement, which causes the incident angle of the light incident on the grating 63 from the prism 61 to coincide with the diffraction angle of the diffracted light having a desired wavelength. Thus, light having a wavelength close to the desired wavelength returns to the housing 30 via the prism 61.

The output coupling mirror 70 faces the window 31a, transmits a part of the laser light output from the window 31a, and reflects another part thereof to return to the internal space of the housing 30 through the window 31a. The output coupling mirror 70 is fixed to a holder (not shown) and is arranged at the internal space of the housing 110.

The grating 63 and the output coupling mirror 70 arranged with the housing 30 interposed therebetween configure a Fabry-Perot resonator, and the housing 30 is arranged on the optical path of the resonator.

The light transmission unit 141 includes high reflection mirrors 141b, 141c as the main configuration. The high reflection mirrors 141b, 141c are fixed to respective holders (not shown) in a state in which their inclination angles are adjusted, and are arranged at the internal space of the housing 110. The high reflection mirrors 141b, 141c highly reflects the laser light. The high reflection mirrors 141b, 141c are arranged on the optical path of the laser light from the output coupling mirror 70. The laser light is reflected by the high reflection mirrors 141b, 141c and travels to a rear mirror 371 of the amplifier 160. At least a part of the laser light is transmitted through the rear mirror 371.

The amplifier 160 amplifies the energy of the laser light output from the laser oscillator 130. The basic configuration of the amplifier 160 is substantially the same as that of the laser oscillator 130. In order to distinguish the components of the amplifier 160 from the components of the laser oscillator 130, the chamber device, the housing, the pair of windows, the pair of electrodes, the insulating portion, the feedthrough, the electrode holder portion, the charger, the pulse power module, and the output coupling mirror of the amplifier 160 are described as a chamber device CH3, a housing 330, a pair of window 331a, 331b, a pair of electrodes 332a, 332b, an insulating portion 333, a feedthrough 334, an electrode holder portion 336, a charger 341, a pulse power module 343, and an output coupling mirror 370. The electrodes 332a, 332b cause discharge for amplifying the laser light from the laser oscillator 130. The pulse power module 343 is a voltage application circuit similarly to the pulse power module 43.

Further, the amplifier 160 is different from the laser oscillator 130 in that the line narrowing module 60 is not included and the rear mirror 371, a support member 400, an output-side holding unit 500, and a rear-side holding unit 600 are included.

The rear mirror 371 is provided between the high reflection mirror 141c and the window 331b and faces to the both thereof. The rear mirror 371 transmits a part of the laser light from the laser oscillator 130 toward the space between the electrodes 332a, 332b, and reflects the laser light amplified by the electrodes 332a, 332b toward the space between the electrodes 332a, 332b.

The output coupling mirror 370 is provided between the window 331a and a beam splitter 153b and faces to the both. The output coupling mirror 370 reflects a part of the laser light amplified by the electrodes 332a, 332b and output toward the space between the electrodes 332a, 332b, and transmits another part of the laser light toward the detection unit 153. For this purpose, the surface of the output coupling mirror 370 facing the window 331a is coated with a partial reflection film having a predetermined reflectance. Hereinafter, the surface of the output coupling mirror 370 on which the partial reflection film is coated is referred to as a main surface.

The output coupling mirror 370 has a circular shape, and the surface facing the window 331a and the surface opposite to the surface are flat surfaces. Configurations of the rear mirror 371 and the output coupling mirror 70 are the same as that of the output coupling mirror 370.

The rear mirror 371 and the output coupling mirror 370 arranged with the housing 330 interposed therebetween configure a resonator in which the laser light amplified by the electrodes 332a, 332b resonates. The housing 330 is arranged on the optical path of the resonator, and the laser light output from the housing 330 reciprocates between the rear mirror 371 and the output coupling mirror 370. The reciprocating laser light is amplified every time the laser light passes through a laser gain space between the electrode 332a and the electrode 332b. A part of the amplified laser light is transmitted through the output coupling mirror 370.

The support member 400 is a flat plate that is longer than the housing 330 and extends in the travel direction of the laser light. One end of the support member 400 is located on a side toward the beam splitter 153b to be described below of the detection unit 153 from the window 331a, and the other end of the support member 400 is located on a side toward the high reflection mirror 141c from the window 331b.

The output-side holding unit 500 is arranged at one end of the support member 400 and holds the output coupling mirror 370, and the rear-side holding unit 600 is arranged at the other end of the support member 400 and holds the rear mirror 371. By the support member 400, the output-side holding unit 500, and the rear-side holding unit 600, the output coupling mirror 370 is arranged between the window 331a and the beam splitter 153b, and the rear mirror 371 is arranged between the window 331b and the high reflection mirror 141c. The output coupling mirror 370 and the rear mirror 371 are relatively positioned by the support member 400, the output-side holding unit 500, and the rear-side holding unit 600. The output-side holding unit 500 and the rear-side holding unit 600 will be described later. The laser light transmitted through the output coupling mirror 370 travels to the detection unit 153.

The detection unit 153 includes the beam splitter 153b and an optical sensor 153c as the main configuration.

The beam splitter 153b is arranged on the optical path of the laser light transmitted through the output coupling mirror 370. The beam splitter 153b transmits the laser light transmitted through the output coupling mirror 370 to an output window 173 with a high transmittance, and reflects a part of the pulse laser light toward a light receiving surface of the optical sensor 153c.

The optical sensor 153c measures the pulse energy of the laser light incident on the light receiving surface of the optical sensor 153c. The optical sensor 153c is electrically connected to the processor 190, and outputs a signal indicating the measured pulse energy to the processor 190. The processor 190 controls the voltage to be applied to the electrodes 32a, 32b of the amplifier 160 based on the signal.

The output window 173 is provided on the opposite side of the output coupling mirror 370 with respect to the beam splitter 153b of the detection unit 153. The output window 173 is provided in a wall of the housing 110. The light transmitted through the beam splitter 153b is output from the output window 173 to the exposure apparatus 200 outside the housing 110. The laser light is, for example, pulse laser light having a center wavelength of 193.4 nm.

The internal spaces of the housings 30, 330 are filled with a purge gas. The purge gas includes an inert gas such as high-purity nitrogen with reduced impurities such as oxygen. The purge gas is supplied from a purge gas supply source (not shown) arranged outside the housing 110 to the internal spaces of the housings 30, 330 through a pipe (not shown).

The display unit 180 is a monitor that displays a state of control by the processor 190 based on a signal from the processor 190.

The processor 190 of the present disclosure is a processing device including a storage device in which a control program is stored and a central processing unit (CPU) that executes the control program. The processor 190 is specifically configured or programmed to perform various processes included in the present disclosure. The processor 190 controls the entire gas laser device 100. The processor 190 is electrically connected to an exposure processor (not shown) of the exposure apparatus 200, and transmits and receives various signals to and from the exposure processor.

The laser gas exhaust device 701 and the laser gas supply device 703 are electrically connected to the processor 190. The laser gas exhaust device 701 includes an exhaust pump (not shown), and exhausts the laser gas from the internal spaces of the housings 30, 330 via a pipe by suction of the exhaust pump according to a control signal from the processor 190. The laser gas supply device 703 supplies the laser gas from a laser gas supply source (not shown) arranged outside the housing 110 to the internal spaces of the housings 30, 330 via a pipe according to a control signal from the processor 190.

Next, the output-side holding unit 500 will be described.

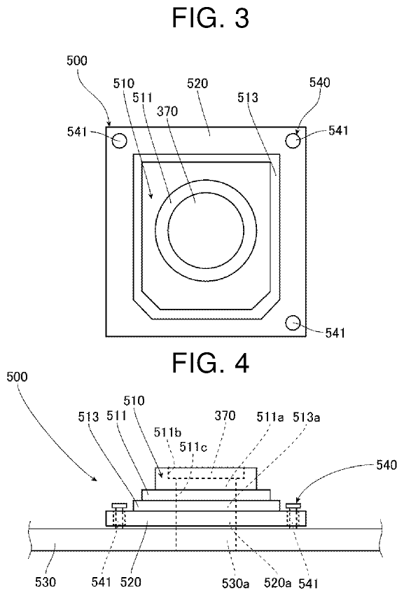

FIG. 3 is a front view of the output-side holding unit 500 of the comparative example. FIG. 4 is a side view of the output-side holding unit 500 shown in FIG. 3.

The output-side holding unit 500 includes a holding portion 510 that holds the output coupling mirror 370, a base member 520 on which the holding portion 510 is arranged, a support member 530 that supports the holding portion 510 via the base member 520, and an angle maintaining mechanism 540. In FIG. 3, the support member 530 is not shown for easy viewing.

The holding portion 510 includes a main body portion 511 that holds the output coupling mirror 370, and a mounting plate 513 to which the main body portion 511 is attached and which is arranged on the base member 520. For easy viewing, in FIG. 2, the holding portion 510 is shown in a simplified manner and the main body portion 511 and the mounting plate 513 are not shown.

The main body portion 511 is provided with a through hole 511a. The through hole 511a includes a circular large-diameter portion 511b and a circular small-diameter portion 511c, and the large-diameter portion 511b is located closer to the window 331a than the small-diameter portion 511c and communicates with the small-diameter portion 511c. The diameter of the large-diameter portion 511b is larger than the diameter of the small-diameter portion 511c, the large-diameter portion 511b is approximately the same size as the output coupling mirror 370, and the output coupling mirror 370 is arranged on the large-diameter portion 511b. Light traveling from the output coupling mirror 370 or light directed to the output coupling mirror 370 passes through the small-diameter portion 511c.

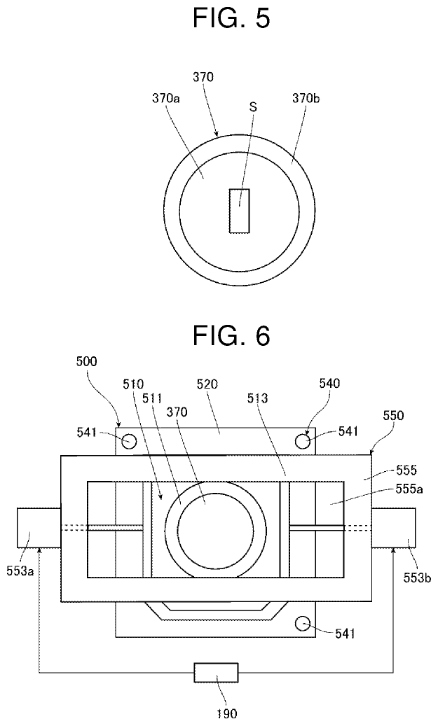

FIG. 5 is a front view of the output coupling mirror 370. An effective region 370a of the output coupling mirror 370 that overlaps the small-diameter portion 511c is a circular region irradiated with light from the window 331a. Further, in the output coupling mirror 370, an ineffective region 370b is provided on the outer side of the effective region 370a. The ineffective region 370b is a ring-shaped region that overlaps a step surface between the large-diameter portion 511b and the small-diameter portion 511c and does not transmit light.

Incidentally, the light traveling from the window 331a to the output coupling mirror 370 is not radiated to the entire effective region 370a of the output coupling mirror 370 but is radiated to a part of the effective region 370a. Therefore, the radiation spot S of the light in the effective region 370a is smaller than the effective region 370a. The shape of the radiation spot S is formed by a mask (not shown) arranged between the window 331a and the output coupling mirror 370. The mask is, for example, a plate-shaped member in which a rectangular transmission hole for transmitting a part of the laser light is formed and blocking the other part of the laser light. Here, the shape of the transmission hole is not limited to the above. The transmission hole is smaller than the circular effective region 370a of the output coupling mirror 370, and the short side and the long side of the rectangular transmission hole are smaller than the diameter of the effective region 370a. As the laser light passes through the transmission hole, light having a rectangular shape travels to the output coupling mirror 370, and the radiation spot S of the light at the effective region 370a is formed into a rectangular shape by the transmission hole. The short side and the long side of the radiation spot S are smaller than the diameter of the effective region 370a.

The mounting plate 513, the base member 520, and the support member 530 are flat plates. When viewed from the front, the mounting plate 513 is larger than the main body portion 511 and smaller than the base member 520, and the base member 520 is smaller than the support member 530. The main body portion 511 is fixed to the mounting plate 513, and the mounting plate 513 is fixed to the base member 520 by screws (not shown). Further, the main body portion 511 is replaceable with respect to the mounting plate 513, and the mounting plate 513 is replaceable with respect to the base member 520.

Circular through holes 513a, 520a, 530a are provided in the mounting plate 513, the base member 520, and the support member 530, respectively. The through hole 513a of the mounting plate 513 communicates with the small-diameter portion 511c of the main body portion 511 and the through hole 520a of the base member 520, and the through hole 520a of the base member 520 communicates with the through hole 530a of the support member 530. Light passes through the through holes 513a, 520a, 530a in a similar manner as through the through hole 511a.

The base member 520 is arranged on the surface of the main surface of the support member 530. The main surface is substantially perpendicular to the optical axis of the laser light output from the window 331a and the extending direction of the support member 400. The support member 530 is long in a direction substantially perpendicular to the extending direction of the support member 400. The holding portion 510 and the base member 520 are arranged on one end side of the main surface of the support member 530. The other end of the support member 530 on the side opposite to the holding portion 510 side is fixed to one end of the support member 400.

The angle maintaining mechanism 540 maintains the inclination angle of the holding portion 510 with respect to the support member 530 at a predetermined angle. For example, a plurality of adjustment screws 541 are used as the angle maintaining mechanism 540, the adjustment screws 541 are screwed into screw holes of the base member 520, and the distal ends thereof are engaged with the support member 530. Thus, the support member 530 supports the holding portion 510 via the base member 520. The inclination of the base member 520 with respect to the support member 530 is adjusted by adjusting the screwing amount of each of the adjustment screws 541. Thus, the inclination of the holding portion 510 with respect to the support member 530 is adjusted, and the inclination angle of the main surface of the output coupling mirror 370 with respect to the support member 530 is adjusted and maintained at the predetermined angle. The predetermined angle may be, for example, an angle at which the energy of the laser light output from the gas laser device 100 is maximized. In this case, for example, the main surface of the output coupling mirror 370 irradiated with light from the window 331a and the main surfaces of the mounting plate 513 and the base member 520 are substantially perpendicular to the optical axis of the light.

The configuration of the angle maintaining mechanism 540 is not limited to the adjustment screws 541, and a gimbal mechanism, a kinematic mount, or the like may be used.

As shown in FIG. 2, the base member 520 and the support member 530 are provided on the side opposite to the window 331a with respect to the output coupling mirror 370.

The rear-side holding unit 600 has the same configuration as the output-side holding unit 500 except that the rear mirror 371 is held, and thus the description thereof will be omitted.

### 2.2 Operation

Next, operation of the gas laser device 100 of the comparative example will be described.

In a state before the gas laser device 100 outputs the laser light, the laser gas is supplied from the laser gas supply device 703 to the internal space of the housing 30. Further, the angle maintaining mechanism 540 maintains the inclination angle of the main surface of the output coupling mirror 370 with respect to the support member 530 at the predetermined angle by adjusting the screwing amount of the adjustment screws 541.

When the gas laser device 100 outputs the laser light, the processor 190 receives a signal indicating a target energy Et and a light emission trigger signal from the exposure processor (not shown) of the exposure apparatus 200. The target energy Et is a target value of the energy of the laser light used in the exposure process. The processor 190 sets a predetermined charge voltage to the charger 41 so that the energy E becomes the target energy Et, and turns ON the switch of the pulse power module 43 in synchronization with the light emission trigger signal. Thus, the pulse power module 43 generates a pulse high voltage from the electric energy held in the charger 41, and applies the high voltage between the electrode 32a and the electrode 32b. When the high voltage is applied, discharge occurs between the electrode 32a and the electrode 32b, the laser medium contained in the laser gas between the electrode 32a and the electrode 32b is brought into an excited state, and light is emitted when the laser medium returns to the ground state. The emitted light resonates between the grating 63 and the output coupling mirror 70, and is amplified every time passing through the discharge space at the internal space of the housing 30, so that laser oscillation occurs. A part of the laser light is transmitted through the output coupling mirror 70, is reflected by the high reflection mirrors 141b, 141c, is transmitted through the rear mirror 371 and the window 31b, and travels into the housing 330.

The processor 190 turns ON the switch of the pulse power module 343 so that discharge occurs when the laser light from the laser oscillator 130 travels to the discharge space in the housing 330. The processor 190 controls the pulse power module 343 such that a high voltage is applied to the electrodes 332a, 332b after a predetermined delay time elapses from the timing at which the switch of the pulse power module 43 is turned ON.

Thus, the laser light incident on the amplifier 160 is amplified and oscillated in the amplifier 160. Further, the laser light traveling to the internal space of the housing 330 is transmitted through the windows 331a, 331b as described above and travels to the rear mirror 371 and the output coupling mirror 370. Thus, the laser light having a predetermined wavelength reciprocates between the rear mirror 371 and the output coupling mirror 370. The laser light is amplified every time passing through the discharge space at the internal space of the housing 30, laser oscillation occurs, and a part of the laser light becomes amplified laser light.

The amplified laser light from the amplifier 160 is transmitted through the output coupling mirror 370 and travels to the beam splitter 153b.

A part of the amplified laser light traveling to the beam splitter 153b is transmitted through the beam splitter 153b and the output window 173 and travels to the exposure apparatus 200, while another part is reflected by the beam splitter 153b and travels to the optical sensor 153c.

The optical sensor 153c receives the amplified laser light and measures the energy E of the received amplified laser light. The optical sensor 153c outputs a signal indicating the measured energy E to the processor 190. The processor 190 performs feedback control on the charge voltages of the chargers 41, 341 so that a difference ΔE between the energy E and the target energy Et falls within an allowable range. When the difference ΔE falls within the allowable range, the laser light is transmitted through the beam splitter 153b and the output window 173 and enters the exposure apparatus 200.

### 2.3 Problem

In the amplifier 160 of the comparative example, since the output coupling mirror 370 is fixed without being moved, one position in the effective region 370a is irradiated with the radiation spot S, so that irradiation of the output coupling mirror 370 with light is performed in a concentrating manner. The higher the intensity of the light is, the faster the output coupling mirror 370 deteriorates. Although the above description has been made using the output coupling mirror 370, the rear mirror 371 of the amplifier 160 and the output coupling mirror 70 of the laser oscillator 130 also deteriorate similarly to the output coupling mirror 370 of the amplifier 160. When the mirrors such as the output coupling mirror 370 of the amplifier 160, the rear mirror 371 of the amplifier 160, and the output coupling mirror 70 of the laser oscillator 130 deteriorate quickly, the replacement frequency of the mirrors increases, and the operating rate of the gas laser device 100 may decrease.

Therefore, in the following embodiments, a gas laser device capable of suppressing a decrease in the operating rate is exemplified.

### 3. Description of Gas Laser Device of First Embodiment

Next, the gas laser device 100 of a first embodiment will be described. Any component same as that described above is denoted by an identical reference sign, and duplicate description thereof is omitted unless specific description is needed. Further, in some drawings, a part of a member may be omitted or simplified for easy viewing.

### 3.1 Configuration

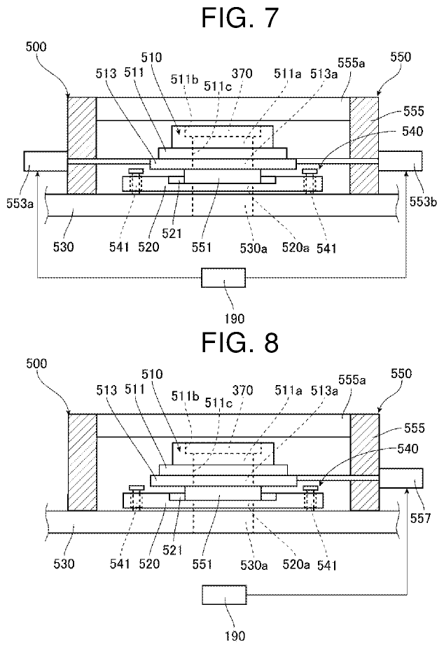

FIG. 6 is a front view of the output-side holding unit 500 of the present embodiment. FIG. 7 is a side view of the output-side holding unit 500 shown in FIG. 6. In FIG. 7, a part of a case 555 is shown in cross section. The configuration of the output-side holding unit 500 of the present embodiment is different from the configuration of the output-side holding unit 500 of the comparative example in the following points. In the output-side holding unit 500 of the present embodiment, the support member 530 supports the holding portion 510 so as to be movable along a plane perpendicular to the optical axis of the light output to the outside from the window 331a. The output-side holding unit 500 further includes a moving mechanism 550 that moves the holding portion 510 with respect to the support member 530 along the plane.

The moving mechanism 550 includes a guide unit 551, cylinders 553a, 553b, and the case 555.

The guide unit 551 guides linear movement of the holding portion 510 in the direction along the above-described plane, that is, in the direction along the support member 530. The direction along the plane is a direction along the short side of the radiation spot S having a rectangular shape, but may be a direction along the long side of the radiation spot S. The guide unit 551 is a linear guide. The guide unit 551 in this case includes a rail provided in the groove 521 of the base member 520, and a slider that is arranged on the rear surface of the mounting plate 513 so as to straddle the rail and slides on the rail. The groove 521 and the guide unit 551 are provided so as not to overlap the through holes 513a, 520a.

The cylinders 553a, 553b sandwich the mounting plate 513 from both sides in the movement direction of the holding portion 510. Shafts of the cylinders 553a, 553b extend in the movement direction of the holding portion 510, and the distal end of the shaft of the cylinder 553a is connected to the side surface of the mounting plate 513, and the distal end of the shaft of the cylinder 553b is connected to the opposite side surface of the mounting plate 513. The cylinders 553a, 553b are electrically connected to the processor 190 and push and pull the mounting plate 513 by movement of their shafts under the control of the processor 190. Specifically, the cylinders 553a, 553b are interlocked with each other, and their shafts move in the longitudinal direction. In this case, the cylinder 553a pushes the mounting plate 513 via the shaft thereof and the cylinder 553b pulls the mounting plate 513 via the shaft thereof, or the cylinder 553a pulls the mounting plate 513 via the shaft thereof and the cylinder 553b pushes the mounting plate 513 via the shaft thereof. The pushing amount of the cylinder 553a is the same as the pulling amount of the cylinder 553b, the pulling amount of the cylinder 553a is the same as the pushing amount of the cylinder 553b, and the pushing amount of the cylinder 553a and the pulling amount of the cylinder 553a are the movement amount of the holding portion 510. Here, the mounting plate 513 may be moved by operation of the cylinders 553a, 553b by an administrator of the gas laser device 100 without the cylinders 553a, 553b being connected to the processor 190. In this case, the cylinder 553a is provided with a spring (not shown) that expands and contracts in the movement direction of the holding portion 510. When the spring expands, the cylinder 553a pushes the mounting plate 513 and the cylinder 553b pulls the mounting plate 513. When the spring contracts, the cylinder 553a pulls the mounting plate 513 and the cylinder 553b pushes the mounting plate 513. The distal ends of the shafts of the cylinders 553a, 553b may be connected to the side surfaces of the main body portion 511. Movement of the holding portion 510 by the cylinders 553a, 553b moves the output coupling mirror 370 via the holding portion 510.

The case 555 is arranged on the support member 530 and surrounds the main body portion 511, the mounting plate 513, and the base member 520 of the output-side holding unit 500. The upper surface of the case 555 is opened, and when the case 555 is viewed from the front, an opening 555a of the case 555 is provided so as to overlap the output coupling mirror 370 even when the output coupling mirror 370 moves or even when the output coupling mirror 370 is stopped without moving. Accordingly, the light from the window 331a is transmitted through the output coupling mirror 370 via the opening 555a. The cylinders 553a, 553b are fixed to the side surfaces of the case 555, and the shafts of the cylinders 553a, 553b penetrate the side surfaces of the case 555, respectively.

The angle maintaining mechanism 540 of the present embodiment maintains the inclination angle of the holding portion 510 with respect to the support member 530 at the predetermined angle regardless of the position of the holding portion 510.

### 3.2 Operation

First, the processor 190 sets the chargers 41, 341 to a stopped state and turns OFF the pulse power modules 43, 343. Thus, the output of light is stopped. Next, the processor 190 causes the cylinders 553a, 553b to push and pull the mounting plate 513, and moves the holding portion 510 along a plane perpendicular to the optical axis of the light output from the window 331a. In this case, the holding portion 510 moves in a direction along the short side of the rectangular radiation spot S, and is guided in the movement direction by the guide unit 551. The movement of the holding portion 510 also moves the output coupling mirror 370. At this time, even when the holding portion 510 and the output coupling mirror 370 move, the radiation spot S does not move. The holding portion 510 moves in a range in which the radiation spot S falls within the effective region 370a and does not overlap the ineffective region 370b. Due to the movement of the holding portion 510 and the output coupling mirror 370, the position of the radiation spot S in the effective region 370a is shifted from the position before the movement of the holding portion 510 and the output coupling mirror 370. At least a part of the radiation spot S after the movement may be shifted from the radiation spot S before the movement. Since the operation of the gas laser device 100 after the position of the radiation spot S is shifted is the same as the operation described in the comparative example, description thereof will be omitted. Further, even after the movement of the output coupling mirror 370, the inclination angle of the main surface of the output coupling mirror 370 with respect to the support member 530 can be maintained at the predetermined angle by adjusting the screwing amount of the adjustment screws 541 in the angle maintaining mechanism 540 as well.

### 3.3 Effect

The gas laser device 100 of the present embodiment includes the chamber device CH3 that includes the electrodes 332a, 332b at the inside thereof to be filled with the laser gas, and that outputs, through the window 331a, light generated from the laser gas when a voltage is applied to the electrodes 332a, 332b. The gas laser device 100 further includes an output coupling mirror 370 that is arranged outside the chamber device CH3 and reflects a part of the light output through the window 331a, and a holding portion 510 that holds the output coupling mirror 370. The gas laser device 100 further includes the support member 530 that supports the holding portion 510 to be movable along a plane perpendicular to the optical axis of the light output through the window 331a, the moving mechanism 550 that moves the holding portion 510 with respect to the support member 530 along the plane, and an angle maintaining mechanism 540 that maintains the inclination angle of the holding portion 510 with respect to the support member 530 at a predetermined angle.

In the above configuration, since the holding portion 510 moves along a plane perpendicular to the optical axis of the light with respect to the support member 530 by the moving mechanism 550, the output coupling mirror 370 held by the holding portion 510 also moves. Due to the movement of the output coupling mirror 370, the position of the radiation spot S of the light on the output coupling mirror 370 is shifted. When the position of the radiation spot S is shifted, local irradiation with light on the output coupling mirror 370 can be suppressed as compared with a case in which the radiation spot S is located at one position of the output coupling mirror 370 without shift of the position of the radiation spot S, and deterioration of the output coupling mirror 370 can be suppressed. When the deterioration of the output coupling mirror 370 is suppressed, the lifetime of the output coupling mirror 370 is extended, increase in the replacement frequency of the output coupling mirror 370 can be suppressed, and decrease in the operating rate of the gas laser device 100 due to replacement can be suppressed. Further, in the above configuration, the angle maintaining mechanism 540 maintains the inclination angle of the holding portion 510 with respect to the support member 530 at the predetermined angle. Therefore, even when the output coupling mirror 370 moves, a change in the inclination angle due to the movement can be suppressed. As a result, the frequency of angle adjustment associated with the movement of the output coupling mirror 370 can be decreased, and decrease in the operating rate of the gas laser device 100 due to the angle adjustment can be suppressed.

### 4. Description of Gas Laser Device of Second Embodiment

Next, the gas laser device 100 of a second embodiment will be described. Any component same as that described above is denoted by an identical reference sign, and duplicate description thereof is omitted unless specific description is needed. Further, in some drawings, a part of a member may be omitted or simplified for easy viewing.

### 4.1 Configuration

FIG. 8 is a side view of the output-side holding unit 500 of the present embodiment. In the output-side holding unit 500 of the present embodiment, the configuration of the moving mechanism 550 is different from the configuration of the moving mechanism 550 of the first embodiment. The moving mechanism 550 of the present embodiment includes an actuator 557 that moves the holding portion 510 instead of the cylinders 553a, 553b.

A shaft of the actuator 557 extends in the movement direction of the holding portion 510, and the distal end of the shaft of the actuator 557 is connected to the side surface of the mounting plate 513. The actuator 557 is electrically connected to the processor 190, and the shaft moves in the longitudinal direction under the control of the processor 190 to push and pull the mounting plate 513 via the shaft. The power source of the actuator 557 may be, for example, a stepping motor, but is not particularly limited.

### 4.2 Operation

Next, operation of the processor 190 of the present embodiment will be described.

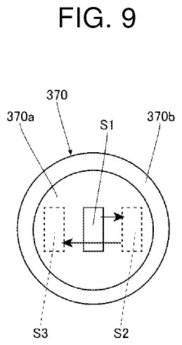

FIG. 9 is a view showing the relative positional relationship between the output coupling mirror 370 and the radiation spot S in the present embodiment. In the output coupling mirror 370 of the present embodiment, the output coupling mirror 370 is moved to three positions of position coordinates P1, P2, P3, and the radiation spot S is moved to three positions in the effective region 370a with the movement of the output coupling mirror 370. Here, the moving destination of the output coupling mirror 370 is different from the three positions.

In FIG. 9, the radiation spots S when the output coupling mirror 370 is moved to the position coordinates P1, P2, P3 are shown as the radiation spots S1, S2, S3, respectively. The radiation spots S1, S2, S3 have the same size. For easy viewing, the radiation spots S2, S3 are indicated by dashed lines. The radiation spots S1, S2, S3 do not overlap each other and are separated from each other. For example, the right side of the radiation spot S1 and the left side of the radiation spot S2, as well as the left side of the radiation spot S1 and the right side of the radiation spot S3 are separated from each other by a distance equal to or more than the short side of the radiation spot S1, and preferably by about three times the distance.

At the position coordinate P1, the center of the radiation spot S1 overlaps the center of the effective region 370a. At the position coordinate P2, the output coupling mirror 370 is moved to the left side of the position coordinate P1, and the center of the radiation spot S2 is located on the right side of the effective region 370a as viewing the output coupling mirror 370 from the front in FIG. 9. At the position coordinate P3, the output coupling mirror 370 is moved to the right side of the position coordinate P1, and the center of the radiation spot S3 is located on the left side of the effective region 370a as viewing the output coupling mirror 370 from the front. The radiation spot S3 is located on the opposite side of the radiation spot S2 with respect to the radiation spot S1. Here, the position coordinates P1, P2, P3 may be located anywhere as long as at least a part of the radiation spot S before the movement does not overlap the radiation spot S after the movement.

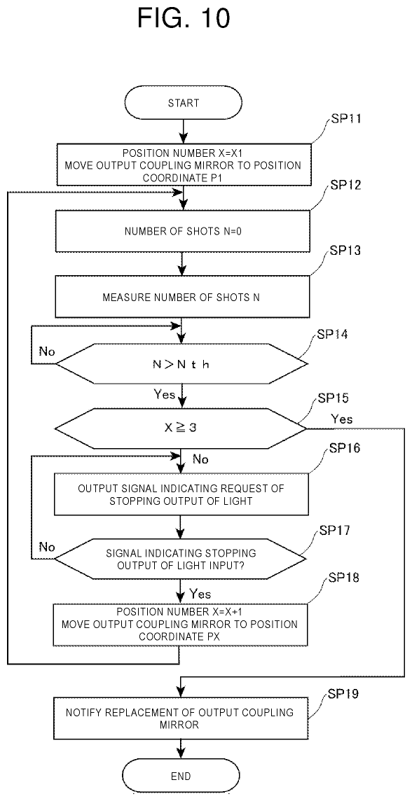

FIG. 10 is a diagram showing an example of a control flowchart of the processor 190 according to the present embodiment. The control flow of the present embodiment includes step SP11 to step SP19.

Parameters are stored in the storage device of the processor 190 of the present embodiment. The parameters include a position number X allocated to the moving destination of the output coupling mirror 370. Since the number of the moving destinations is three as described above, position numbers X=1, X=2, X=3 are allocated to the moving destinations of the output coupling mirror 370. The position coordinates P1, P2, P3 are associated with the position numbers X=1, X=2, X=3.

In the start state shown in FIG. 10, similarly to the first embodiment, the processor 190 sets the chargers 41, 341 to the stopped state and sets the pulse power modules 43, 343 to be OFF. Thus, the output of light is stopped.

### (Step SP11)

In the present step, the processor 190 sets the position number X to X=1, and reads the position coordinate P1 associated with the position number X=1 from the parameters. Next, the processor 190 controls the actuator 557 to move the output coupling mirror 370 to the position coordinate P1 via the holding portion 510. When the output coupling mirror 370 is moved to the position coordinate P1, the processor 190 controls the actuator 557 to stop the output coupling mirror 370 via the holding portion 510, and advances the flow to step SP12.

### (Step SP12)

In the present step, the processor 190 sets the number of shots N of the amplified laser light received by the optical sensor 153c to zero.

### (Step SP13)

In the present step, as described in the comparative example, the processor 190 sets a predetermined charge voltage to the chargers 41, 341 and turns ON the switches of the pulse power modules 43, 343. A part of the amplified laser light from the amplifier 160 is transmitted through the output coupling mirror 370 and travels to the beam splitter 153b. A part of the amplified laser light traveling to the beam splitter 153b is reflected by the beam splitter 153b and travels to the optical sensor 153c. The optical sensor 153c receives the amplified laser light and outputs, to the processor 190, a signal indicating that the amplified laser light has been received. When the input of the signal starts, the processor 190 starts integration of the number of times of reception of the signal and advances the flow to step SP14. Alternatively, the optical sensor 153c receives the amplified laser light and starts measuring the number of shots N of the received amplified laser light. The optical sensor 153c outputs a signal indicating the measured number of shots N to the processor 190 correspondingly. When the input of the signal starts, the processor 190 advances the flow to step SP14.

Here, in the present step, since the output coupling mirror 370 is located at the position coordinate P1, the radiation spot S1 overlaps the output coupling mirror 370.

### (Step SP14)

In the present step, when the number of shots N is equal to or less than a threshold Nth, the processor 190 repeats step SP14. When the number of shots N is more than the threshold Nth, the processor 190 advances the flow to step SP15. The threshold Nth is input to the storage device of the processor 190 as a parameter. The threshold Nth may be, for example, 20 billion pulse shots, but can be changed as appropriate.

### (Step SP15)

In the present step, when the position number X is smaller than X=3, the processor 190 advances the flow to step SP16. When the position number X is equal to or more than X=3, the processor 190 advances the flow to step SP19.

### (Step SP16)

In the present step, the processor 190 outputs, to the exposure apparatus 200, a signal indicating a request for stopping the output of light. When the signal is output to the exposure apparatus 200, the processor 190 advances the flow to step SP17.

### (Step SP17)

In the present step, when a signal indicating stop of the output of light is not input from the exposure apparatus 200 to the processor 190, the processor 190 returns the flow to step SP16. When the signal indicating stop of the output of light is input from the exposure apparatus 200 to the processor 190, the processor 190 stops the chargers 41, 341 and turns OFF the switches of the pulse power modules 43, 343. As a result, the output of light is stopped, and the processor 190 advances the flow to step SP18.

Incidentally, the gas laser device 100 is required to stably output desired laser light for a long time, but when laser oscillation is performed for a long time, impurities are generated in the housing 330 of the chamber device CH3. The impurities absorb the laser light or deteriorate the state of discharge. Therefore, when impurities accumulate in the housing 330 of the chamber device CH3, the intensity of the laser light decreases, and the gas laser device 100 may not be able to output the laser light satisfying the performance required from the exposure apparatus 200 due to the impurities. In this case, in step SP17, the processor 190 may exhaust the laser gas at the inside of the housing 330 of the chamber device CH3 by the laser gas exhaust device 701, and then supply a new laser gas including the laser medium to the inside of the housing 330 by the laser gas supply device 703. In this case, the processor 190 controls the gas exhaust by the laser gas exhaust device 701 and the gas supply by the laser gas supply device 703 so that the laser gas at the inside of the housing 330 of the chamber device CH3 is replaced while the application of the voltage is stopped. By the replacement of the laser gas, the impurities are discharged from the inside of the housing 330 together with the laser gas, and is reduced in quantity at the inside of the housing 330. The processor 190 advances the flow to step SP18 as the input of the signal indicating stop of the output of light is confirmed regardless of the end of the laser gas replacement.

### (Step SP18)

In the present step, the processor 190 sets the position number X obtained by adding 1 to the present position number X as the new position number X. Next, the processor 190 controls the actuator 557 to move the output coupling mirror 370 to a position coordinate PX corresponding to the new position number X via the holding portion 510. When the flow advances to step SP18 for the first time, the processor 190 reads the position number X=2 from the parameters and moves the output coupling mirror 370 to the position coordinate P2. When the flow advances to step SP18 for the second time, the processor 190 reads the position number X=3 from the parameters and moves the output coupling mirror 370 to the position coordinate P3. When the output coupling mirror 370 is moved to the position coordinate P2 or P3, the processor 190 controls the actuator 557 to stop the output coupling mirror 370 at the position coordinate P2 or P3 via the holding portion 510, and returns the flow to step SP12. When the output coupling mirror 370 is located at the position coordinate P2 and the flow advances from step SP12 to step SP13, the radiation spot S2 overlaps the output coupling mirror 370. When the output coupling mirror 370 is located at the position coordinate P3 and the flow advances from step SP12 to step SP13, the radiation spot S3 overlaps the output coupling mirror 370. In this way, the output coupling mirror 370 is moved to three positions, and the radiation spot S is moved to three positions.

Here, the movement of the output coupling mirror 370 in the present step may be performed during the replacement of the laser gas described as an optional step in step SP17.

### (Step SP19)

In the present step, the processor 190 outputs a signal indicating replacement of the output coupling mirror 370 to the display unit 180, and the display unit 180 notifies replacement of the output coupling mirror 370. When the processor 190 outputs the signal to the display unit 180, the flow ends.

### 4.3 Effect

In the gas laser device 100 of the present embodiment, the processor 190 controls the actuator 557 to stop the output coupling mirror 370 at a first position, move thereafter from the first position to a second position, and then stop at the second position via the holding portion 510 as described in step SP11, step SP18, and step SP13. For example, the first position is the position coordinate P1, and the second position in this case is the position coordinate P2 that is different from the first position. Alternatively, the first position is the position coordinate P2, and the second position in this case is the position coordinate P3. The processor 190 controls the pulse power module 343 to apply a voltage to the electrodes 332a, 332b each time after the output coupling mirror 370 is stopped at the first position and the second position.

In the above configuration, light is generated when the voltage is applied to the electrodes 332a, 332b, and the light is radiated to the output coupling mirror 370 stopped at the first position and the output coupling mirror 370 stopped at the second position. Therefore, since the radiation spot S of the light to be radiated to the output coupling mirror 370 is located at a plurality of positions, a plurality of positions of the output coupling mirror 370 can be used for outputting the light from the gas laser device 100 as compared with a case in which the radiation spot S is located at one position. In addition, the utilization range may be widened in the output coupling mirror 370. Further, in the above configuration, since the output coupling mirror 370 is moved by the actuator 557, the burden on the administrator of the gas laser device 100 can be reduced compared with a case in which the administrator manually moves the output coupling mirror 370. Further, in the above configuration, a voltage is applied to the electrodes 332a, 332b and light is output after the output coupling mirror 370 is stopped. Therefore, as compared with a case in which a voltage is applied to the electrodes 332a, 332b and light is output during the output coupling mirror 370 is moved, it is possible to suppress an influence on the performance of the laser light such as the divergence angle of the laser light due to variation in the alignment of the output coupling mirror 370.

Further, in the gas laser device 100 of the present embodiment, as described in step SP13 to step SP17, after the output coupling mirror 370 is stopped at the first position and a voltage is applied to the electrodes 332a, 332b, the processor 190 controls the pulse power module 343 to stop the application of the voltage to the electrodes 332a, 332b during a period after the output coupling mirror 370 starts moving and before the output coupling mirror 370 is stopped at the second position.

In the above configuration, the output of light is stopped until the output coupling mirror 370 moves from the first position to the second position and stops at the second position. In this case, it is possible to perform maintenance of the gas laser device 100, such as replacement of the laser gas inside the housing 330 of the chamber device CH3, while the output of light is stopped.

Further, in the gas laser device 100 of the present embodiment, as described in step SP17, the processor 190 controls the laser gas exhaust device 701 and the laser gas supply device 703 so that the laser gas inside the chamber device CH3 is replaced while the application of the voltage is stopped and the output of the light is stopped.

In the above configuration, the laser gas can be replaced before the output coupling mirror 370 is stopped at the second position and the voltage is applied to the electrodes 332a, 332b. In this case, due to the replacement of the laser gas, even when the output coupling mirror 370 is moved to the second position and a voltage is applied to the electrodes 332a, 332b, the gas laser device 100 can output light with reduction in intensity suppressed as compared with a case in which the laser gas is not replaced.

Further, in the gas laser device 100 of the present embodiment, as described in step SP17 and step SP18, the processor 190 may control the actuator 557 to move the output coupling mirror 370 from the first position to the second position via the holding portion 510 during the replacement of the laser gas.

In the above configuration, since the output coupling mirror 370 is moved during the replacement of the laser gas, the downtime of the gas laser device 100 can be shortened as compared with a case in which the output coupling mirror 370 is moved after the replacement of the laser gas.

Further, in the gas laser device 100 of the present embodiment, at least a part of the radiation spot S2 of the light that is radiated to the output coupling mirror 370 when the output coupling mirror 370 is stopped at the second position does not overlap the radiation spot S1 of the light that is radiated to the output coupling mirror 370 when the output coupling mirror 370 is stopped at the first position.

In the above configuration, at positions in the output coupling mirror 370 where the radiation spots S1, S2 do not overlap each other, deterioration can be suppressed as compared with positions in the output coupling mirror 370 where the radiation spots S1, S2 overlap each other.

### 5. Description of Gas Laser Device of Third Embodiment

Next, the gas laser device 100 of a third embodiment will be described. Any component same as that described above is denoted by an identical reference sign, and duplicate description thereof is omitted unless specific description is needed. Further, in some drawings, a part of a member may be omitted or simplified for easy viewing.

### 5.1 Configuration

The configuration of the gas laser device 100 according to the present embodiment is similar to the configuration of the gas laser device 100 of the second embodiment, and therefore description thereof is omitted.

### 5.2 Operation

Next, operation of the processor 190 of the present embodiment will be described.

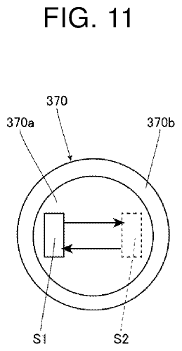

FIG. 11 is a view showing the relative positional relationship between the output coupling mirror 370 and the radiation spot S in the present embodiment. The output coupling mirror 370 of the present embodiment moves to reciprocate between the position coordinate P1 and the position coordinate P2.

In FIG. 11, the radiation spots S when the output coupling mirror 370 is moved respectively to the position coordinates P1, P2 are shown as the radiation spots S1, S2. For easy viewing, the radiation spot S2 is indicated by dashed lines. The radiation spots S1, S2 do not overlap each other and are separated from each other.

The position coordinate P1 of the present embodiment corresponds to the position coordinate P3 of the second embodiment, and at the position coordinate P1 of the present embodiment, the center of the radiation spot S1 is located on the left side of the effective region 370a. The position coordinate P2 of the present embodiment corresponds to the position coordinate P2 of the second embodiment, and at the position coordinate P2 of the present embodiment, the center of the radiation spot S2 is located on the right side of the effective region 370a.

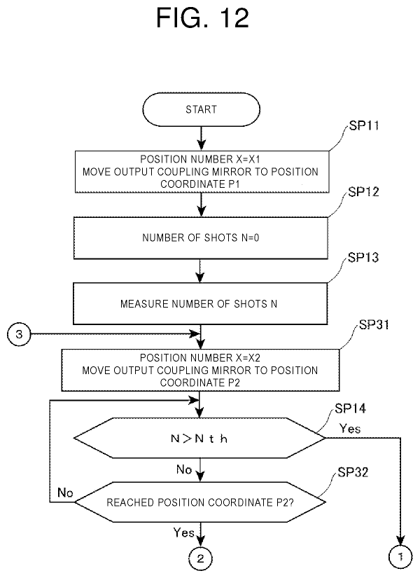

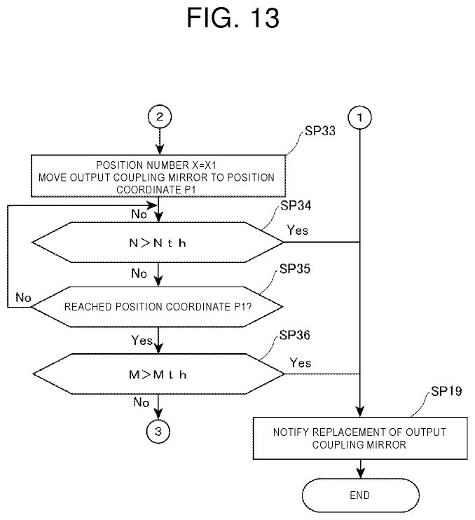

FIG. 12 is a diagram showing a part of an example of a control flowchart of the processor 190 of the present embodiment, and FIG. 13 is a diagram showing a remaining part of the example of the control flowchart of the processor 190 of the present embodiment.

The control flow of the present embodiment includes step SP11 to step SP14 and step SP19 of the second embodiment, and step SP31 to step SP36.

After the processor 190 advances the flow in the order of step SP11 to step SP13, the processor 190 advances the flow to step SP31. In the start state, the number of times of reciprocation M to be described later is zero.

### (Step SP31)

In the present step, the processor 190 sets the position number X to X=2, and reads the position coordinate P2 associated with the position number X=2 from the parameters. Next, the processor 190 controls the actuator 557 to move the output coupling mirror 370 to the position coordinate P2 from the position coordinate P1 via the holding portion 510. As a result, the output coupling mirror 370 starts moving to the position coordinate P2. The repetition frequency of the pulse oscillation is, for example, 6 kHz, and the moving speed of the output coupling mirror 370 is, for example, 0.1 μm/pulse or more and 1.0 μm/pulse or less. Here, the moving speed may be constant regardless of the repetition frequency of the pulse oscillation. The movement of the output coupling mirror 370 causes the radiation spot S to be gradually shifted. In the gradually shifting radiation spot S, a part of the radiation spot before the movement overlaps a part of the radiation spot after the movement. The processor 190 advances the flow to step SP14.

### (Step SP14)

In the present step, when the number of shots N is more than the threshold Nth, the processor 190 advances the flow to step SP19. When the number of shots N is equal to or less than the threshold Nth, the processor 190 advances the flow to step SP32.

### (Step SP32)

In the present step, when the output coupling mirror 370 has not reached the position coordinate P2, the processor 190 returns the flow to step SP14. When the output coupling mirror 370 has reached the position coordinate P2, the processor 190 advances the flow to step SP33.

### (Step SP33)

In the present step, the processor 190 sets the position number X to X=1, and reads the position coordinate P1 associated with the position number X=1 from the parameters. Next, the processor 190 controls the actuator 557 to move the output coupling mirror 370 to the position coordinate P1 from the position coordinate P2 via the holding portion 510. That is, the processor 190 returns the output coupling mirror 370 to the position coordinate P1. As a result, the output coupling mirror 370 starts moving to the position coordinate P1, and the processor 190 advances the flow to step SP34.

### (Step SP34)

In the present step, when the number of shots N is more than the threshold Nth, the processor 190 advances the flow to step SP19. When the number of shots N is equal to or less than the threshold Nth, the processor 190 advances the flow to step SP35.

### (Step SP35)

In the present step, when the output coupling mirror 370 has not reached the position coordinate P1, the processor 190 returns the flow to step SP34. When the output coupling mirror 370 has reached the position coordinate P1, it can be understood that the output coupling mirror 370 has reciprocated between the position coordinate P1 and the position coordinate P2, and the processor 190 advances the flow to step SP36.

### (Step SP36)

In the present step, when the number of times of reciprocation M is more than a threshold Mth, the processor 190 advances the flow to step SP19. When the number of times of reciprocation M is equal to or less than the threshold Mth, the processor 190 adds 1 to the current number of times of reciprocation M, and returns the flow to step SP31. The threshold Mth is stored in the storage device of the processor 190 as a parameter and is, for example, 1 million times, but can be changed as appropriate.

### 5.3 Effect

In the gas laser device 100 of the present embodiment, the processor 190 controls the actuator 557 to move the output coupling mirror 370 from the first position to the second position being different from the first position via the holding portion 510 during application of the voltage as described in the order of step SP11 to step SP13, step SP31, step SP14, and SP32. At this time, the repetition frequency of the pulse oscillation is, for example, 6 kHz, and the moving speed of the output coupling mirror 370 is, for example, 0.1 μm/pulse or more and 1.0 μm/pulse or less.

In the above configuration, the gas laser device 100 continues to output light during the movement of the output coupling mirror 370. Therefore, as compared with a case in which the output of the light is stopped during the movement of the output coupling mirror 370, and the downtime of the gas laser device 100 can be shortened while suppressing deterioration of the output coupling mirror 370. Further, the output coupling mirror 370 moves at the moving speed of, for example, 0.1 μm/pulse or more and 1.0 μm/pulse or less with the repetition frequency being 6 kHz. In this case, it is possible to suppress an influence on the performance of the laser light such as the divergence angle of the laser light due to variation in the alignment of the output coupling mirror 370.

Further, in the gas laser device 100 of the present embodiment, the processor 190 controls the actuator 557 to cause the output coupling mirror 370 to reciprocate between the first position and the second position via the holding portion 510 during the application of the voltage.

In the above configuration, compared with a case in which the output coupling mirror 370 is moved between the first position and the second position only in one direction, a usage period of the output coupling mirror 370 may be elongated.

Although the above embodiments have been described as an example, the present disclosure is not limited thereto, and can be modified as appropriate.

In the gas laser device 100 of each of the above embodiments, description has been made using the output-side holding unit 500. However, since the configuration of the output-side holding unit 500 is the same as that of the rear-side holding unit 600, the rear-side holding unit 600 can obtain the same effects as those of the output-side holding unit 500. Further, the output-side holding unit 500 can obtain the same effects as described above even when it is used on the laser oscillator 130 side. In the gas laser device 100, the same rear mirror as the rear mirror 371 may be arranged in place of the line narrowing module 60. In this case, the rear mirror may be a total reflection mirror. The rear mirror may be held by the rear-side holding unit 600. In this case, the rear-side holding unit 600 can obtain the same effects as the output-side holding unit 500.

The movement of the output coupling mirror 370 is linear movement, but may be other movement such as rotational movement. The base member 520 is not necessarily arranged, and the holding portion 510 may be arranged on the support member 530. In this case, the adjustment screws 541 may be screwed into the base member 520.

The description above is intended to be illustrative and the present disclosure is not limited thereto. Therefore, it would be obvious to those skilled in the art that various modifications to the embodiment of the present disclosure would be possible without departing from the spirit and the scope of the appended claims. Further, it would be also obvious to those skilled in the art that embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of the any thereof and any other than A, B, and C.

What is claimed is:

1. A gas laser device comprising:
a chamber device including electrodes at an inside thereof to be filled with laser gas and configured to output, through a window to an outside thereof, light generated from the laser gas when a voltage is applied to the electrodes;
a mirror arranged at the outside of the chamber device and configured to reflect at least a part of the light output through the window;
a holding portion holding the mirror;
a support member configured to support the holding portion to be movable along a plane perpendicular to an optical axis of the light output through the window;
a moving mechanism configured to move the holding portion with respect to the support member along the plane; and
an angle maintaining mechanism configured to maintain an inclination angle of the holding portion with respect to the support member at a predetermined angle.

2. The gas laser device according to claim 1, further comprising:
a voltage application circuit configured to apply the voltage to the electrodes; and
a processor configured to control the voltage application circuit so that the voltage is applied to the electrodes,
wherein the moving mechanism includes an actuator configured to move the holding portion with respect to the support member along the plane, and
the processor controls the actuator so that the mirror stops at a first position, moves thereafter to a second position being different from the first position, and then stops at the second position via the holding portion, and controls the voltage application circuit so that the voltage is applied to the electrodes each time after the mirror is stopped at the first position and at the second position.

3. The gas laser device according to claim 2,
wherein the processor controls the voltage application circuit so that the application of the voltage to the electrodes is stopped during a period from starting the moving of the mirror from the first position to the stopping thereof at the second position, after the mirror is stopped at the first position and the voltage is applied to the electrodes.

4. The gas laser device according to claim 3, further comprising:
a gas exhaust device configured to exhaust the laser gas at the inside of the chamber device; and
a gas supply device configured to supply the laser gas to the inside of the chamber device,
wherein the processor controls the gas exhaust device and the gas supply device so that the laser gas at the inside of the chamber device is replaced while the application of the voltage is stopped.

5. The gas laser device according to claim 4,
wherein the processor controls the actuator so that the mirror is moved from the first position to the second position via the holding portion during the replacement of the laser gas.

6. The gas laser device according to claim 2,
wherein, at least a part of a radiation spot of the light radiated to the mirror when the mirror is stopped at the second position does not overlap the radiation spot of the light radiated to the mirror when the mirror is stopped at the first position.

7. The gas laser device according to claim 1, further comprising:
a voltage application circuit configured to apply the voltage to the electrodes; and
a processor configured to control the voltage application circuit so that the voltage is applied to the electrodes,
wherein the moving mechanism includes an actuator configured to move the holding portion with respect to the support member along the plane, and
the processor controls the actuator so that the mirror is moved from a first position to a second position being different from the first position via the holding portion during the application of the voltage.

8. The gas laser device according to claim 7,
wherein the processor controls the actuator so that the mirror reciprocates between the first position and the second position via the holding portion during the application of the voltage.

9. The gas laser device according to claim 1, further comprising an optical resonator configured of a rear mirror and an output coupling mirror,
wherein the chamber device is arranged between the rear mirror and the output coupling mirror,
the window is configured of a pair of windows,
the rear mirror reflects at least a part of the light traveling from one of the windows,
the output coupling mirror reflects a part of the light traveling from the other of the windows and transmits a remaining part of the light traveling from the other of the windows, and
the mirror is at least one of the rear mirror and the output coupling mirror.

10. The gas laser device according to claim 1, further comprising an optical resonator configured of a grating and an output coupling mirror,
wherein the chamber device is arranged between the grating and the output coupling mirror,
the window is configured of a pair of windows,
the grating reflects the light traveling from one of the windows,
the output coupling mirror reflects a part of the light traveling from the other of the windows and transmits a remaining part of the light traveling from the other of the windows, and
the mirror is the output coupling mirror.

11. An electronic device manufacturing method, comprising:
generating laser light using a gas laser device;
outputting the laser light to an exposure apparatus; and
exposing a photosensitive substrate to the laser light in the exposure apparatus to manufacture an electronic device,
the gas laser device including:
a chamber device including electrodes at an inside thereof to be filled with laser gas and configured to output, through a window to an outside thereof, light generated from the laser gas when a voltage is applied to the electrodes;
a mirror arranged at the outside of the chamber device and configured to reflect at least a part of the light output through the window;
a holding portion holding the mirror;
a support member configured to support the holding portion to be movable along a plane perpendicular to an optical axis of the light output through the window;
a moving mechanism configured to move the holding portion with respect to the support member along the plane; and
an angle maintaining mechanism configured to maintain an inclination angle of the holding portion with respect to the support member at a predetermined angle.
